(19) United States
(12) Patent Application Publication
(10) Pub. No.: US 2016/0146860 A1
(43) Pub. Date: May 26, 2016

(54) CURRENT DETECTOR AND CURRENT DETECTION METHOD

(71) Applicant: Hitachi Metals, Ltd., Tokyo (JP)

(72) Inventors: Naoki FUTAKUCHI, Hitachinaka (JP); Naofumi CHIWATA, Mito (JP); Takahiro FUTATSUMORI, Mito (JP); Hiroshi SAKAGUCHI, Hitachi (JP)

(73) Assignee: Hitachi Metals, Ltd., Tokyo (JP)

(21) Appl. No.: 14/944,602

(22) Filed: Nov. 18, 2015

(30) Foreign Application Priority Data
Nov. 25, 2014 (JP) 2014-238167

(51) Int. Cl. G01R 15/20; G01R 19/00

(52) U.S. Cl. CPC G01R 15/207; G01R 19/0092; G01R 15/205

(57) ABSTRACT

A current detector includes a plurality of current paths arranged in parallel, magnetic detection portions that are provided corresponding to the plurality of current paths and have magnetic detection elements for detecting strength of a magnetic field generated by an electric current flowing through each of the current paths, a temperature sensor for detecting a temperature of the magnetic detection portions, correction circuits for correcting an output of the magnetic detection elements based on a result of detection by the temperature sensor, and detection circuits for detecting a magnitude of the electric current flowing through each of the current paths based on the output corrected by the correction circuits. The magnetic detection portions and the temperature sensor are housed, together with a portion of the plurality of current paths, in a molded package. A number of the temperature sensor is less than that of the magnetic detection portions.

The present application is based on Japanese patent application No. 2014-238167 filed on Nov. 25, 2014, the entire contents of which are incorporated herein by reference.

### BACKGROUND OF THE INVENTION

1. Field of the Invention

The invention relates to a current detector for detecting electric current flowing through a current path by using a magnetic detection element, and a current detection method.

2. Description of the Related Art

For example, in the field of motor drive technology for hybrid and electric vehicles etc., relatively large current is used and there is thus a demand for current detectors capable of non-contact measurement of high current. Some of such current detectors use a magnetic detection element for detecting strength of a magnetic field generated by electric current being measured, thereby detecting the magnitude of the electric current being measured. The magnetic detection element can be a Hall element using the Hall effect, an AMR element using the anisotropic magnetoresistive (AMR) effect, a GMR element using the giant magnetoresistive (GMR) effect or a TMR element using the tunnel magnetoresistive (TMR) effect etc.

When an electric current flows through a current path, Joule heat is generated in the current path and is transferred to the magnetic detection element of which temperature thus changes. Since the output of the magnetic detection element changes according to temperature, it is necessary to detect the temperature by a temperature sensor and then to correct the output of the magnetic detection element. Where the magnetic detection element is a magnetoresistive effect element, a bias magnet of the magnetoresistive effect element and a temperature sensor for measuring temperature of the bias magnet are housed in a housing portion and temperature characteristics of output signals of the magnetic detection element are corrected based on output signals of the temperature sensor (see, e.g., JP-A-2013-242301).

### SUMMARY OF THE INVENTION

Where multiple current paths are arranged in parallel as in current paths for supplying currents to a three-phase motor etc., the temperature of the magnetic detection elements corresponding to the current paths is difficult to accurately detect by single temperature sensor. In order to accurately detect the temperature of each of the magnetic detection elements to perform the accurate temperature correction, it is necessary to provide a temperature sensor for each of the magnetic detection elements corresponding to the current paths. Thus, the number of the temperature sensors may increase so as to cause an increase in the cost of the entire current detector.

It is an object of the invention to provide a current detector that can make accurately the temperature correction even by using fewer temperature sensor than before, as well as a current detection method.

(1) According to one embodiment of the invention, a current detector comprises:

a plurality of current paths arranged in parallel;

magnetic detection portions that are provided corresponding to the plurality of current paths and have magnetic detection elements for detecting strength of a magnetic field generated by an electric current flowing through each of the current paths;

a temperature sensor for detecting a temperature of the magnetic detection portions;

correction circuits for correcting an output of the magnetic detection elements based on a result of detection by the temperature sensor; and

detection circuits for detecting a magnitude of the electric current flowing through each of the current paths based on the output corrected by the correction circuits,

wherein the magnetic detection portions and the temperature sensor are housed, together with a portion of the plurality of current paths, in a molded package, and wherein a number of the temperature sensor is less than that of the magnetic detection portions.

(2) According to another embodiment of the invention, a current detection method comprises:

providing magnetic detection portions that are provided corresponding to a plurality of current paths arranged in parallel and have magnetic detection elements for detecting strength of a magnetic field generated by an electric current flowing through each of the current paths;

providing a temperature sensor for detecting a temperature of the magnetic detection portions such that a number of the temperature sensor is less than that of the magnetic detection portions;

housing the magnetic detection portions and the temperature sensor together with a portion of the plurality of current paths in a molded package;

correcting an output of the magnetic detection elements of not less than two of the magnetic detection portions based on a result of detection by the temperature sensor; and

detecting a magnitude of the electric current flowing through each of the current paths based on the corrected output.

### Effects of the Invention

According to one embodiment of the invention, a current detector can be provided that can make accurately the temperature correction even by using fewer temperature sensor than before so as to decrease the cost of the entire current detector, as well as a current detection method.

### BRIEF DESCRIPTION OF THE DRAWINGS

Next, the present invention will be explained in more detail in conjunction with appended drawings, wherein:

FIG. 1 is an illustration diagram showing a configuration of magnetic detection portions of current detectors in embodiments of the present invention;

FIG. 2A is a perspective view showing a current detector in a first embodiment of the invention;

FIG. 2B is a cross sectional view taken along a line A-A in FIG. 2A;

FIG. 3 is an illustration diagram showing an example of temperature distribution in a molded package;

FIG. 4A is a perspective view showing a current detector in a second embodiment of the invention;

FIG. 4B is a cross sectional view taken along a line B-B in FIG. 4A;

FIG. 5A is a perspective view showing a current detector in a third embodiment of the invention;

FIG. 5B is a cross sectional view taken along a line C-C in FIG. 5A;

FIG. 6A is a perspective view showing a current detector in a fourth embodiment of the invention; and

FIG. 6B is a cross sectional view taken along a line D-D in FIG. 6A.

### DETAILED DESCRIPTION OF THE PREFERRED EMBODIMENTS

### Configuration of Magnetic Detection Portion

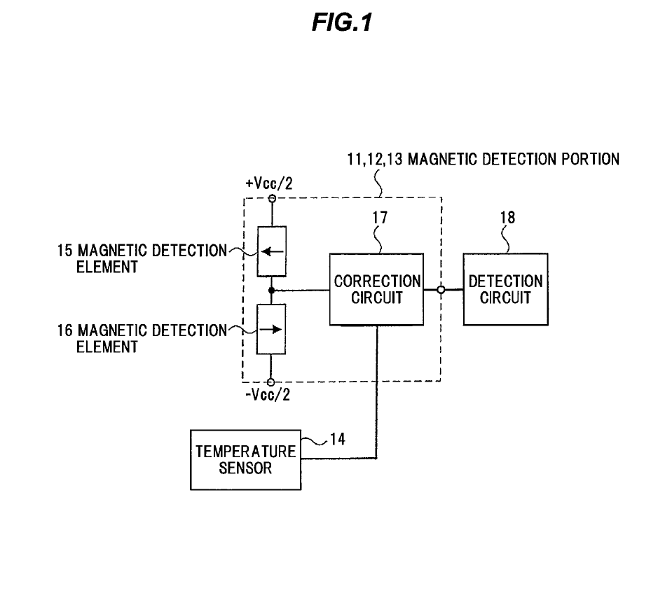

FIG. 1 is an illustration diagram showing a configuration of magnetic detection portions of current detectors in the embodiments of the invention. Magnetic detection portions 11 to 13 of the current detector have a half-bridge configuration with magnetic detection elements 15 and 16. Each of the magnetic detection elements 15 and 16 is constructed from a GMR element and detects strength of a magnetic field generated by an electric current flowing through a current path.

The GMR element has a higher sensitivity than the Hall element. In more detail, while the minimum detectable magnetic field of the Hall element is 0.5 Oe (0.05 mT in terms of magnetic flux density in the air), that of the GMR element is 0.02 Oe (0.002 mT in terms of magnetic flux density in the air). In addition, the response speed of the GMR element is faster than other magnetic detection elements such as the Hall element. Furthermore, unlike, e.g., a coil, etc., which senses a change in a magnetic field, the GMR element directly detects the magnetic field itself and thus can be highly responsive to even a very small change in the magnetic field. Therefore, use of the GMR element as the magnetic detection elements 15 and 16 improves accuracy of detecting a magnetic field generated by an electric current flowing through a current path.

The magnetic detection elements 15 and 16 are connected in series and are arranged so that magnetosensitive axis directions indicated by arrows are opposite to each other. A driving voltage +Vcc/2 is applied to a terminal on the magnetic detection element 15 side and a driving voltage −Vcc/2 is applied to a terminal on the magnetic detection element 16 side. Then, outputs signals are output from a junction between the magnetic detection elements 15 and 16. A correction circuit 17 performs temperature correction of the output signals based on a result of detection by a temperature sensor 14. A detection circuit 18 detects the magnitude of the electric current flowing through the current path based on the output signals corrected by the correction circuit 17.

The magnetic detection elements 15 and 16 and the correction circuit 17 are arranged on one chip. Alternatively, the magnetic detection elements 15 and 16 may be arranged on separate chips. As another alternative, the correction circuit 17 may be provided outside the chip. Or, the detection circuit 18 may be arranged on the chip.

Although a bias coil for generating a bias magnetic field to be applied to the GMR element is provided on each of the magnetic detection portions 11 to 13, the illustration of the bias coil is omitted in FIG. 1. The magnetic detection portions 11 to 13 may alternatively have a full-bridge configuration with four magnetic detection elements.

### First Embodiment

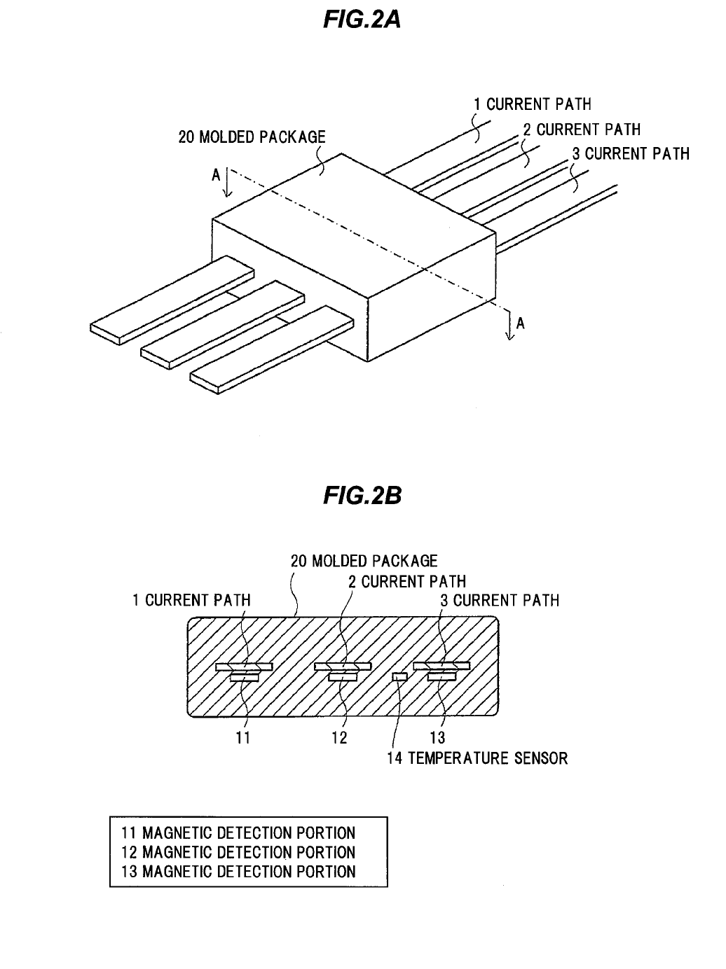

FIG. 2A is a perspective view showing a current detector in the first embodiment of the invention. In FIG. 2A, three current paths 1 to 3 are three-phase current paths and are arranged in parallel. Each of the current paths 1 to 3 corresponds to any one of three phases U, V and W. Each of the current paths 1 to 3 is a plate shaped busbar of which width direction coincides with an alignment direction of the current paths 1 to 3. The width direction of the busbar may be orthogonal to the alignment direction of the current paths 1 to 3.

A molded package 20 is provided on the current paths 1 to 3 so as to house a portion of the current paths 1 to 3. For a sealing material constituting the molded package 20, a highly thermally conductive material among heat resistant resins such as epoxy resin or ceramic materials such as alumina is used. A material with improved thermal conductivity obtained by, e.g., modifying a molecular structure of a conventional sealing material or by mixing a base resin such as polycarbonate with a filler as an additive may alternatively be used.

FIG. 2B is a cross sectional view taken along a line A-A in FIG. 2A. The magnetic detection portions 11 to 13 respectively corresponding to the current paths 1 to 3 are provided in the molded package 20. The magnetic detection portion 11 detects strength of a magnetic field generated by an electric current flowing through the corresponding current path 1. The magnetic detection portion 12 detects strength of a magnetic field generated by an electric current flowing through the corresponding current path 2. The magnetic detection portion 13 detects strength of a magnetic field generated by an electric current flowing through the corresponding current path 3.

The magnetic detection portions 11 to 13 are housed together with a portion of the current paths 1 to 3 in the molded package 20. Therefore, heat generated by the current paths 1 to 3 is transferred to the sealing material of the molded package 20, the temperature inside the molded package 20 becomes substantially uniform and a temperature difference between the magnetic detection portions 11 to 13 is reduced.

The temperature sensor 14 is provided inside the molded package 20. In the first embodiment, the temperature sensor 14 is shared among the magnetic detection portions 11 to 13 and is arranged at the same height as that of the magnetic detection portions 11 to 13. The respective correction circuits 17 of the magnetic detection portions 11 to 13 correct the outputs of the magnetic detection elements 15 and 16 of the magnetic detection portions 11 to 13 based on a result of detection by one temperature sensor 14. The temperatures of the magnetic detection portions 11 to 13 are accurately detected by only one temperature sensors 14 (few in number), and temperature correction is performed highly accurately.

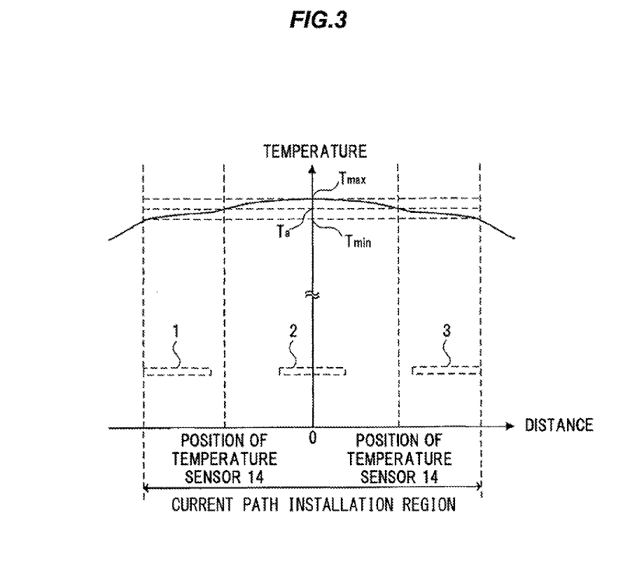

FIG. 3 is an illustration diagram showing an example of temperature distribution in the molded package. In FIG. 3, the horizontal axis indicates a distance from a position on the line passing through the center of the current path 2 illustrated by a dotted line to positions away therefrom in the alignment direction of the current paths 1 to 3, and the vertical axis indicates temperature at a predetermined height on the upper or lower side of the current paths 1 to 3. The temperature inside the molded package 20 is highest at the position on the line passing through the center of the current path 2 and gradually decreases with increasing the distance from the center of the current path 2. Then, the temperature decreases largely out of the installation region of the current paths 1 to 3 (beyond the left edge of the current path 1 illustrated by a dotted line and beyond the right edge of the current path 3 illustrated by a dotted line in FIG. 3). When the maximum value of the temperature within the installation region of the current paths 1 to 3 is Tmax, the minimum value is Tmin and the median value is Ta, the temperature sensor 14 is arranged at a position in the molded package 20 where temperature is substantially the median value Ta of temperature distribution within the installation region of the plural current paths 1 to 3.

In the first embodiment in which the three current paths are provided, the position at which temperature is the median value Ta is a position shifted to the current path 1 side from the center between the current paths 1 and 2, and also a position shifted to the current path 3 side from the center between the current paths 2 and 3.

Since the temperature sensor 14 is arranged at a position in the molded package 20 where temperature is substantially the median value of temperature distribution within the installation region of the plural current paths 1 to 3, a difference between the temperature detected by the temperature sensor 14 and the actual temperature of each of the magnetic detection portions 11 to 13 is reduced.

### Functions and Effects of the First Embodiment

The following functions and effects are obtained in the first embodiment.
(1) The magnetic detection portions 11 to 13 and the temperature sensor 14 are housed together with a portion of the plural current paths 1 to 3 and the number of the temperature sensors 14 provided is smaller than the number of the magnetic detection portions 11 to 13. In this configuration, only a few temperature sensors 14 can accurately detect the temperatures of the magnetic detection portions 11 to 13, thereby allowing for highly accurate temperature correction. Therefore, it is possible to highly accurately detect the magnetic fields generated by the electric currents flowing through the current paths 1 to 3 and thereby to accurately detect the electric currents flowing through the current paths 1 to 3, while reducing the cost of the detector.

(2) By arranging the temperature sensor 14 at a position in the molded package 20 where temperature is substantially the median value of temperature distribution within the installation region of the plural current paths 1 to 3, it is possible to reduce detection errors, thereby allowing for more highly accurate temperature correction.

### Second Embodiment

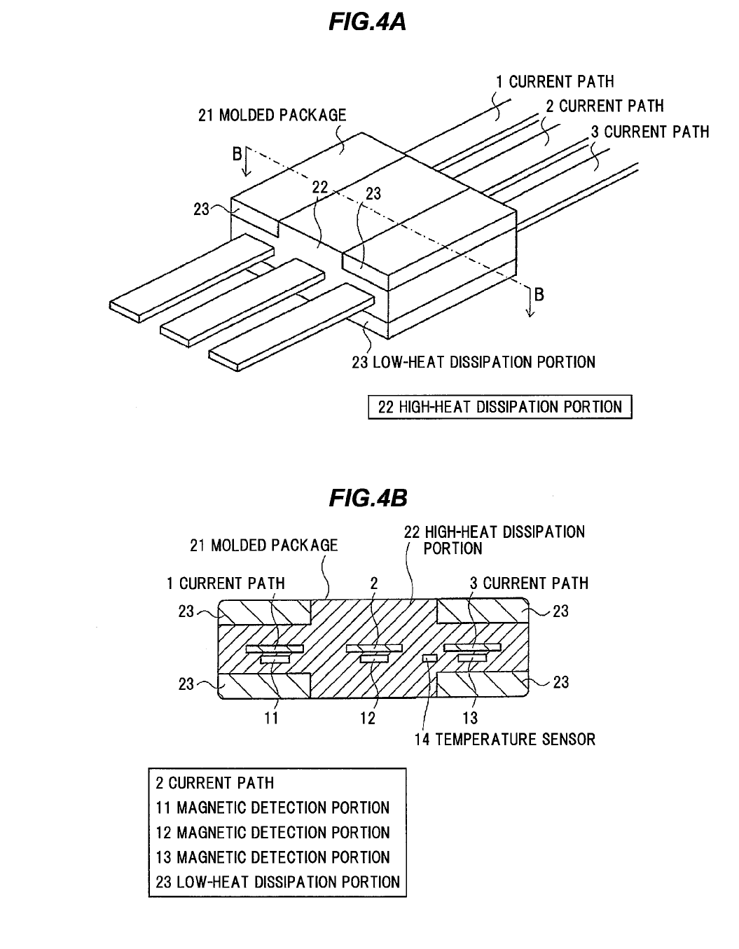

FIG. 4A is a perspective view showing a current detector in the second embodiment of the invention. A molded package 21 in the second embodiment has a high-heat dissipation portion 22 having a high thermal conductivity and low-heat dissipation portions 23 having a lower thermal conductivity than the high-heat dissipation portion 22. The remaining configuration is the same as the first embodiment shown in FIG. 2A.

In the high-heat dissipation portion 22, a sealing material is filled substantially without voids. The low-heat dissipation portion 23 has, e.g., a honeycomb structure in which the sealing material has hollows. Due to the difference in the filling fraction of the sealing material, the low-heat dissipation portion 23 has a lower thermal conductivity than the high-heat dissipation portion 22.

Alternatively, the high-heat dissipation portion 22 and the low-heat dissipation portion 23 may be formed of materials having different thermal conductivities.

FIG. 4B is a cross sectional view taken along a line B-B in FIG. 4A. In the molded package 21, the low-heat dissipation portions 23 are provided at the edges in the alignment direction of the plural current paths 1 to 3. When a portion of the current paths 1 to 3 arranged in parallel is housed in the molded package 21, the temperature distributed in the molded package 21 is highest at the center in the alignment direction of the current paths 1 to 3 and is slightly lower at the edges. By configuring the low-heat dissipation portions 23 having a lower thermal conductivity than the high-heat dissipation portion 22 to be provided at the edges in the alignment direction of the plural current paths 1 to 3, the heat-dissipation effect is lower at the edges provide with the low-heat dissipation portions 23 than in the high-heat dissipation portion 22 and the temperature inside the molded package 21 becomes more uniform.

### Functions and Effects of the Second Embodiment

The second embodiment achieves the same functions and effects as (1) and (2) described for the first embodiment.

Furthermore, by configuring the low-heat dissipation portions 23 having a lower thermal conductivity than the high-heat dissipation portion 22 having a high thermal conductivity to be provided at the edges of the molded package 21 in the alignment direction of the plural current paths 1 to 3, it is possible to further equalize the temperature inside the molded package 21.

In addition, by configuring the low-heat dissipation portion 23 so that the filling fraction of the sealing material thereof is lower than that of the high-heat dissipation portion 22, it is possible to use the same material to form the high-heat dissipation portion 22 and the low-heat dissipation portion 23.

### Third Embodiment

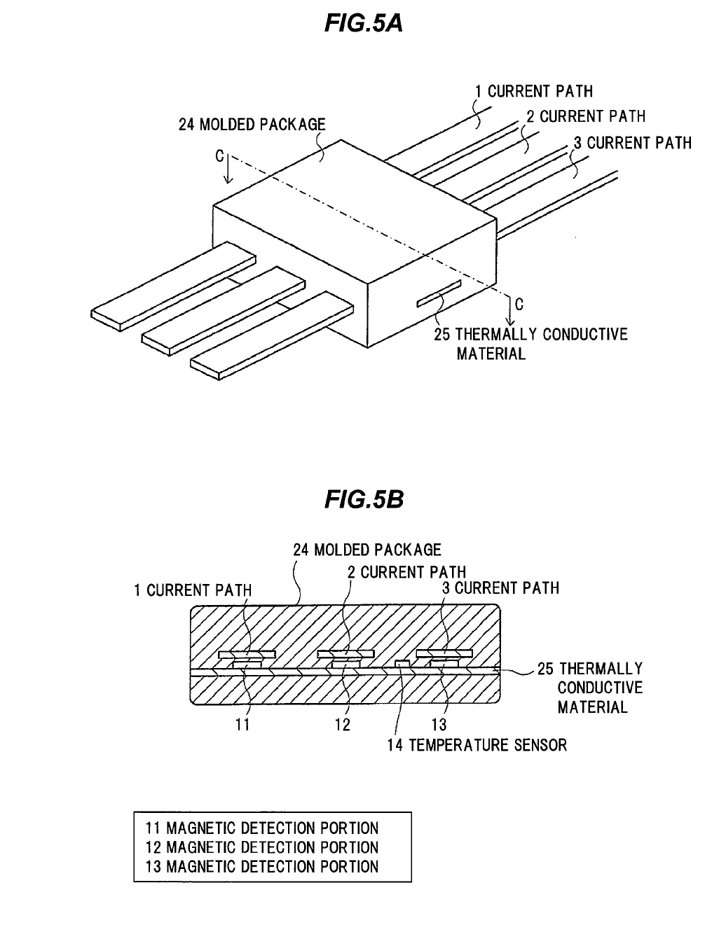

FIG. 5A is a perspective view showing a current detector in the third embodiment of the invention. In the third embodiment, a thermally conductive material 25 to equalize temperature inside a molded package 24 is housed in the molded package 24. The remaining configuration is the same as the first embodiment shown in FIG. 2A. Alternatively, the thermally conductive material 25 may be housed in the molded package 21 in the second embodiment shown in FIG. 4A.

The thermally conductive material 25 is formed of a material having a higher thermal conductivity than a sealing material of the molded package 24. Good moldability is required for the sealing material of the molded package 24 but is not required for a material of the thermally conductive material 25 which only needs to have a plate shape, a foil shape or a rod shape, etc. Therefore, it is possible to use various highly thermally conductive materials to form the thermally conductive material 25.

In detail, the thermally conductive material 25 may be, e.g., a metal such as an aluminum sheet, a copper sheet, an aluminum foil and a copper foil. In case that the thermally conductive material 25 is an electrical conductor, the magnetic detection portions 11 to 13 and the temperature sensor 14 each have an electrode on a surface other than the surface in contact with the thermally conductive material 25. Alternatively, a substrate having a circuit pattern may be used as the thermally conductive material 25, such that electrodes of the elements constituting the magnetic detection portions 11 to 13 and the temperature sensor 14, etc., are connected to the circuit pattern (in this case, the magnetic detection portions 11 to 13 and the temperature sensor 14, etc., may have the electrodes on any surfaces). Additionally, in this case, the circuit pattern connected to the electrodes of the elements constituting the magnetic detection portions 11 to 13 and the temperature sensor 14, etc., may be exposed from the molded package.

FIG. 5B is a cross sectional view taken along a line C-C in FIG. 5A. In the molded package 24, the thermally conductive material 25 is placed along the alignment direction of the plural current paths 1 to 3. The temperature inside the molded package 24 in the alignment direction of the plural current paths 1 to 3 is further equalized by the thermally conductive material 25.

In the third embodiment, the magnetic detection portions 11 to 13 and the temperature sensor 14 are provided in contact with the thermally conductive material 25. Thus, the temperature of each of the magnetic detection portions 11 to 13 becomes substantially the same as the temperature of the thermally conductive material 25, resulting in that a difference between the temperature detected by the temperature sensor 14 and the actual temperature of each of the magnetic detection portions 11 to 13 is further reduced.

### Functions and Effects of the Third Embodiment

The third embodiment achieves the same functions and effects as (1) and (2) described for the first embodiment.

In addition, by housing the thermally conductive material 25 in the molded package 24, it is possible to further equalize the temperature inside the molded package 24.

Furthermore, by providing the magnetic detection portions 11 to 13 and the temperature sensor 14 so as to be in contact with the thermally conductive material 25, it is possible to further reduce the difference between the temperature detected by the temperature sensor 14 and the actual temperature of each of the magnetic detection portions 11 to 13.

### Fourth Embodiment

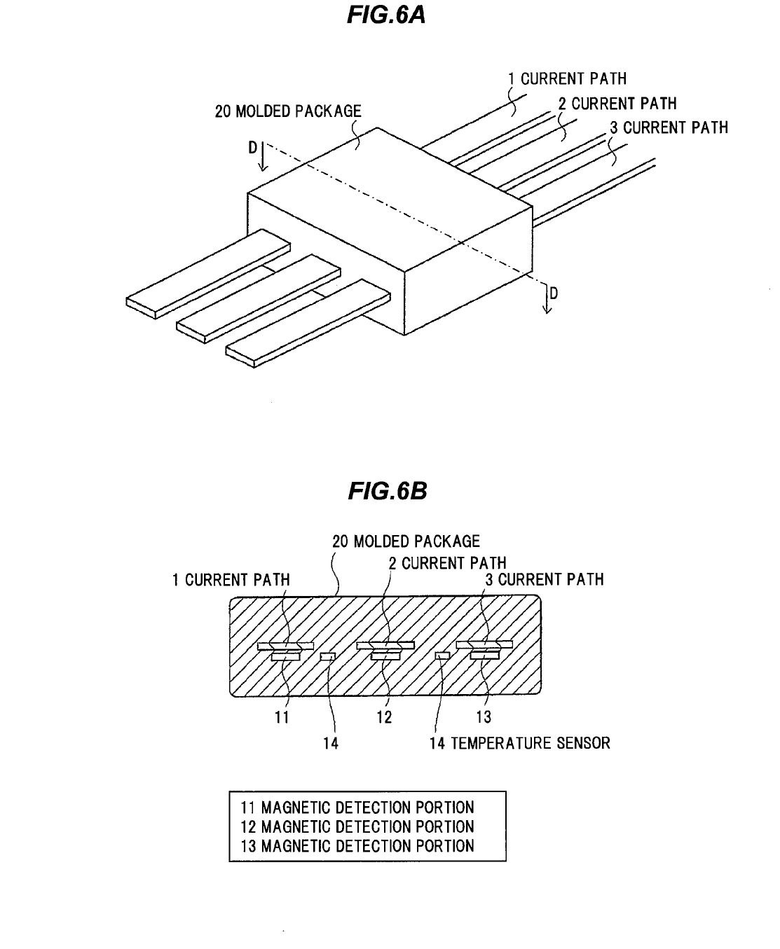

FIG. 6A is a perspective view showing a current detector in the fourth embodiment of the invention and FIG. 6B is a cross sectional view taken along a line D-D in FIG. 6A. In the fourth embodiment, plural temperature sensors 14 are housed in the molded package 20. The remaining configuration is the same as the first embodiment shown in FIG. 2A. Alternatively, the plural temperature sensors 14 may be housed in the molded package 21 in the second embodiment shown in FIG. 4A, or may be housed in the molded package 24 in the third embodiment shown in FIG. 5A.

In the fourth embodiment, two temperature sensors 14, which are fewer than the magnetic detection portions 11 to 13, are arranged at symmetrical positions with the current path 2 interposed therebetween. The temperature sensors 14 are located at the positions, indicated by dotted lines in FIG. 3, in the molded package 20 where temperature is substantially the median value Ta of temperature distribution within the installation region of the plural current paths 1 to 3.

During the normal operation, temperature correction of the outputs of the magnetic detection elements 15 and 16 of the magnetic detection portions 11 to 13 is performed based on the average of the outputs of the two temperature sensors 14. The temperature of each of the magnetic detection portions 11 to 13 is detected more accurately, and temperature correction is performed more highly accurately. Meanwhile, when one of the temperature sensors 14 fails, the output of the other non-faulty temperature sensor 14 is used for temperature correction of the outputs of the magnetic detection elements 15 and 16 of the magnetic detection portions 11 to 13.

### Functions and Effects of the Fourth Embodiment

The fourth embodiment achieves the same functions and effects as (1) and (2) described for the first embodiment.

In addition, plural temperature sensors 14 are housed in the molded package 20. Therefore, even when some of the plural temperature sensors 14 fail, it is possible to perform temperature correction of the outputs of the magnetic detection elements 15 and 16 of the magnetic detection portions 11 to 13 by using the outputs of the non-faulty temperature sensors 14. In addition, the temperature correction of the outputs of the magnetic detection elements 15 and 16 of the magnetic detection portions 11 to 13 based on the average of the outputs of the plural temperature sensors 14 allows for more highly accurate temperature correction.

### SUMMARY OF THE EMBODIMENTS

Technical ideas understood from the embodiments will be described below citing the reference numerals, etc., used for the embodiments. However, each reference numeral described below is not intended to limit the constituent elements in the claims to the members, etc., specifically described in the embodiments.

[1] A current detector, comprising: a plurality of current paths (1, 2, 3) arranged in parallel; magnetic detection portions (11, 12, 13) that are provided to respectively correspond to the current paths (1, 2, 3) and each have magnetic detection elements (15, 16) for detecting strength of a magnetic field generated by an electric current flowing through each current path (1, 2, 3); a temperature sensor(s) (14) for detecting temperatures of the magnetic detection portions (11, 12, 13); correction circuits (17) for correcting outputs of the magnetic detection elements (15, 16) based on a result of detection by the temperature sensor(s) (14); and detection circuits (18) for detecting the respective magnitudes of the electric currents flowing through the current paths (1, 2, 3) based on the outputs corrected by the correction circuits (17), wherein the magnetic detection portions (11, 12, 13) and the temperature sensor(s) (14) are housed, together with a portion of the plurality of current paths (1, 2, 3), in a molded package (20/21/24), and the number of the temperature sensors (14) provided is smaller than the number of the magnetic detection portions (11, 12, 13).

[2] The current detector, wherein the temperature sensor(s) (14) is arranged at a position in the molded package (20/21/24) where temperature is substantially the median value of temperature distribution within an installation region of the plurality of current paths (1, 2, 3).

[3] The current detector, wherein the molded package (21) comprises a high-heat dissipation portion (22) having a high thermal conductivity and low-heat dissipation portions (23) that have a lower thermal conductivity than the high-heat dissipation portion (22) and are located at edges in an alignment direction of the plurality of current paths (1, 2, 3).

[4] The current detector, wherein the low-heat dissipation portion (23) is configured that a filling fraction of a sealing material thereof is lower than that of the high-heat dissipation portion (22).

[5] The current detector, wherein a thermally conductive material (25) to equalize the temperature inside the molded package (24) is housed in the molded package (24).

[6] The current detector, wherein the magnetic detection portions (11, 12, 13) and the temperature sensor(s) (14) are provided in contact with the thermally conductive material (25).

[7] The current detector, wherein the number of the current paths (1, 2, 3) provided is not less than three, and the number of the temperature sensors (14) provided is not less than two but smaller than the number of the magnetic detection portions (11, 12, 13).

[8] A current detection method, comprising: providing magnetic detection portions (11, 12, 13) that are provided to correspond to a plurality of current paths (1, 2, 3) arranged in parallel and each have magnetic detection elements (15, 16) for detecting strength of a magnetic field generated by an electric current flowing through each current path (1, 2, 3); providing a temperature sensor(s) (14) for detecting temperatures of the magnetic detection portions (11, 12, 13) so that the number of the temperature sensors (14) is smaller than the number of the magnetic detection portions (11, 12, 13); housing the magnetic detection portions (11, 12, 13) and the temperature sensor(s) (14) together with a portion of the plurality of current paths (1, 2, 3) in a molded package (20/21/24); correcting outputs of the magnetic detection elements (15, 16) of not less than two of the magnetic detection portions (11, 12, 13) based on a result of detection by the one temperature sensor (14); and detecting the magnitude of the electric current flowing through each current path (1, 2, 3) based on the corrected outputs.

[9] The method, wherein the temperature sensor(s) (14) is arranged at a position in the molded package (20/21/24) where temperature is substantially the intermediate value of temperature distribution within an installation region of the plurality of current paths (1, 2, 3).

[10] The method, wherein a high-heat dissipation portion (22) having a high thermal conductivity and low-heat dissipation portions (23) having a lower thermal conductivity than the high-heat dissipation portion (22) are provide in the molded package (21), and the low-heat dissipation portions (23) are located at edges of the molded package (21) in an alignment direction of the plurality of current paths (1, 2, 3).

[11] The method, wherein the low-heat dissipation portion (23) is configured that a filling fraction of a sealing material thereof is lower than that of the high-heat dissipation portion (22).

[12] The method, wherein a thermally conductive material (25) is housed in the molded package (24) to equalize the temperature inside the molded package (24).

[13] The method, wherein the magnetic detection portions (11, 12, 13) and the temperature sensor(s) (14) are provided in contact with the thermally conductive material (25).

[14] The method, wherein the number of the current paths (1, 2, 3) provided is not less than three, and the number of the temperature sensors (14) provided is not less than two but smaller than the number of the magnetic detection portions (11, 12, 13).

Although the embodiments of the invention have been described, the invention according to claims is not to be limited to the embodiments. Further, please note that all combinations of the features described in the embodiments are not necessary to solve the problem of the invention.

The invention can be appropriately modified and implemented without departing from the gist thereof. For example, although the GMR elements are used as the magnetic detection elements 15 and 16 in the embodiments, other magnetic detection elements such as Hall elements, AMR elements or TMR elements may be used.

In addition, although three current paths 1 to 3 are provided in the embodiments, the number of the current paths is not limited thereto and may be two or not less than four. The number of the temperature sensors 14 is also not limited to one or two as long as fewer than the magnetic detection portions (the same number as the current paths).

What is claimed is:

1. A current detector, comprising:
a plurality of current paths arranged in parallel;
magnetic detection portions that are provided corresponding to the plurality of current paths and have magnetic detection elements for detecting strength of a magnetic field generated by an electric current flowing through each of the current paths;
a temperature sensor for detecting a temperature of the magnetic detection portions
correction circuits for correcting an output of the magnetic detection elements based on a result of detection by the temperature sensor; and
detection circuits for detecting a magnitude of the electric current flowing through each of the current paths based on the output corrected by the correction circuits,
wherein the magnetic detection portions and the temperature sensor are housed, together with a portion of the plurality of current paths, in a molded package, and
wherein a number of the temperature sensor is less than that of the magnetic detection portions.

2. The current detector according to claim 1, wherein the temperature sensor is arranged at a position in the molded package where temperature is substantially a median value of temperature distribution within an installation region of the plurality of current paths.

3. The current detector according to claim 1, wherein the molded package comprises a high-heat dissipation portion with a high thermal conductivity and a low-heat dissipation portion with a lower thermal conductivity than the high-heat dissipation portion, and
wherein the low-heat dissipation portion is disposed at an edge in an alignment direction of the plurality of current paths.

4. The current detector according to claim 3, wherein the low-heat dissipation portion is in filling fraction of a sealing material lower than the high-heat dissipation portion.

5. The current detector according to claim 1, wherein the molded package comprises a thermally conductive material housed in the molded package to equalize a temperature inside the molded package.

6. The current detector according to claim 5, wherein the magnetic detection portions and the temperature sensor are provided in contact with the thermally conductive material.

7. The current detector according to claim 1, wherein a number of the current paths is not less than three, and
wherein the number of the temperature sensor is not less than two and less than the number of the magnetic detection portions.

8. A current detection method, comprising:
providing magnetic detection portions that are provided corresponding to a plurality of current paths arranged in parallel and have magnetic detection elements for detecting strength of a magnetic field generated by an electric current flowing through each of the current paths;
providing a temperature sensor for detecting a temperature of the magnetic detection portions such that a number of the temperature sensor is less than that of the magnetic detection portions;
housing the magnetic detection portions and the temperature sensor together with a portion of the plurality of current paths in a molded package;
correcting an output of the magnetic detection elements of not less than two of the magnetic detection portions based on a result of detection by the temperature sensor; and
detecting a magnitude of the electric current flowing through each of the current paths based on the corrected output.

9. The method according to claim 8, wherein the temperature sensor is arranged at a position in the molded package where temperature is substantially an intermediate value of temperature distribution within an installation region of the plurality of current paths.

10. The method according to claim 8, wherein the molded package comprises a high-heat dissipation portion with a high thermal conductivity and a low-heat dissipation portion with a lower thermal conductivity than the high-heat dissipation portion, and
wherein the low-heat dissipation portion is disposed at an edge in an alignment direction of the plurality of current paths.

11. The method according to claim 10, wherein the low-heat dissipation portion is in filling fraction of a sealing material lower than the high-heat dissipation portion.

12. The method according to claim 8, wherein the molded package comprises a thermally conductive material housed in the molded package to equalize the temperature inside the molded package.

13. The method according to claim 12, wherein the magnetic detection portions and the temperature sensor are provided in contact with the thermally conductive material.

14. The method according to claim 8, wherein a number of the current paths is not less than three, and
wherein the number of the temperature sensor is not less than two and less than the number of the magnetic detection portions.
